(19) United States
(12) Patent Application Publication
(10) Pub. No.: US 2009/0098309 A1
(43) Pub. Date: Apr. 16, 2009

(54) In-Situ Etching Of Shadow Masks Of A Continuous In-Line Shadow Mask Vapor Deposition System

(75) Inventors: Thomas Peter Brody, Pittsburgh, PA (US); Joseph A. Marcanio, Greensburg, PA (US)

Correspondence Address: THE WEBB LAW FIRM, P.C., 700 KOPPERS BUILDING, 436 SEVENTH AVENUE, PITTSBURGH, PA, 15219, US

(73) Assignee: ADVANTECH GLOBAL, LTD, Tortola (VG)

(21) Appl. No.: 12/250,150

(22) Filed: Oct. 13, 2008

Related U.S. Application Data
(60) Provisional application No. 60/979,957, filed on Oct. 15, 2007.

(51) Int. Cl. B05D 5/12

(52) U.S. Cl. 427/534

(57) ABSTRACT

In a method of using and cleaning one or more shadow masks of a shadow mask vapor deposition system used to form an electronic device, a substrate is advanced through series connected deposition vacuum vessels. As the substrate advances through each deposition vacuum vessel, material from a material deposition source positioned in the deposition vacuum vessel is deposited on the substrate through a shadow mask positioned therein. The material is also deposited on a surface of the shadow mask that faces the one material deposition source. Following the deposit of material on the surface of the shadow mask in at least one deposition vacuum vessel, a reactive gas is introduced into the deposition vacuum vessel absent the substrate therein. The reactive gas is then ionized to remove the material deposited on the shadow mask.

### CROSS-REFERENCE TO RELATED APPLICATION

This application claims priority from U.S. Provisional Patent Application No. 60/979,957, filed Oct. 15, 2007, which is incorporated herein by reference.

### BACKGROUND OF THE INVENTION

1. Field of the Invention

The present invention relates to cleaning of shadow masks of a continuous in-line shadow mask vapor deposition system in-situ.

2. Description of Related Art

An exemplary, continuous in-line shadow mask vapor deposition system is disclosed in U.S. Pat. No. 6,943,066, which is incorporated herein by reference. A problem with such system is that, heretofore, it was necessary to remove each shadow mask from the system for cleaning and subsequent return to the system in order to avoid the build-up of deposition material on the face and in the apertures of each shadow mask, which build-up adversely affected the dimensions of the pattern being deposited on a substrate via the shadow mask.

The embodiment described hereinafter seeks to overcome the foregoing problem with the prior art in-line shadow mask vapor deposition system.

### SUMMARY OF THE INVENTION

The invention is a method of using and cleaning one or more shadow masks of a shadow mask vapor deposition system used to form an electronic device. The method includes (a) advancing a substrate through a plurality of series connected deposition vacuum vessels, with each deposition vacuum vessel having at least one material deposition source and a shadow mask positioned therein; (b) depositing on the substrate in the presence of a vacuum in each deposition vacuum vessel the material from the at least one material deposition source positioned in the deposition vacuum vessel through the shadow mask positioned therein, wherein said material is also deposited on a surface of the shadow mask that faces the one material deposition source; (c) following the deposit in step (b) of the material on the surface of the shadow mask in at least one deposition vacuum vessel of said plurality of series connected deposition vacuum vessels, introducing a reactive gas into the one deposition vacuum vessel when the one deposition vacuum vessel has no substrate therein; and (d) ionizing the reactive gas in the one deposition vacuum vessel of said plurality of series connected deposition vacuum vessels whereupon the ionized gas removes the material deposited on the shadow mask.

The method can further include (e) advancing another substrate through the plurality of series connected deposition vacuum vessels; (f) depositing on the other substrate in the presence of a vacuum in each deposition vacuum vessel the material from the at least one material deposition source positioned in the deposition vacuum vessel through the shadow mask positioned therein, wherein said material is also deposited on a surface of the shadow mask that faces the one material deposition source; (g) following the deposit in step (f) of the material on the surface of the shadow mask in at least one deposition vacuum vessel of said plurality of series connected deposition vacuum vessels, introducing a reactive gas into the one deposition vacuum vessel when the one deposition vacuum vessel has no substrate therein; and (h) ionizing the reactive gas in the one deposition vacuum vessel of said plurality of series connected deposition vacuum vessels whereupon the ionized gas removes the material deposited on the shadow mask.

In step (d), the ionized gas can remove the material deposited on the shadow mask by sputtering.

In step (c), the pressure of the reactive gas in the one deposition vacuum vessel can be between 1 millitorr and 500 millitorr.

The reactive gas can be either CF₄ or SF₆ when the material deposited on the shadow mask is an insulator. The insulator can be SiO₂.

The reactive gas can be a chlorine type gas when the material deposited on the shadow mask is electrically conductive. The chlorine type gas can include one or a combination of Cl₂ and BCl₃. The electrically conductive material can be either Cu or Al.

The reactive gas can be either trimethylamine, the combination of CH₄/H₂/Ar or the combination of H₂/Ar when the material deposited on the shadow mask is a semiconductor. The semiconductor can be either CdS, CdTe or CdSe.

The invention is also a method of using and cleaning one or more shadow masks of a shadow mask vapor deposition system used to form an electronic device. The method includes (a) introducing a substrate into a deposition vacuum vessel that includes a material deposition source and a shadow mask therein; (b) depositing on the substrate in the presence of a vacuum in the deposition vacuum vessel the material from the material deposition source through the shadow mask, wherein said material is also deposited on a surface of the shadow mask that faces the material deposition source; (c) following the deposit in step (b) of the material on the surface of the shadow mask in the deposition vacuum vessel, introducing a reactive gas into the deposition vacuum vessel in the absence of the substrate therein; and (d) ionizing the reactive gas in the deposition vacuum vessel whereupon the ionized gas removes the material deposited on the shadow mask.

The method can further include (e) introducing another substrate into the deposition vacuum vessel; (f) depositing on the other substrate in the presence of a vacuum in the deposition vacuum vessel the material from the material deposition source through the shadow mask, wherein said material is also deposited on a surface of the shadow mask that faces the material deposition source; (g) following the deposit in step (f) of the material on the surface of the shadow mask in the deposition vacuum vessel, introducing a reactive gas into the deposition vacuum vessel in the absence of the other substrate therein; and (h) ionizing the reactive gas in the deposition vacuum vessel whereupon the ionized gas removes the material deposited on the shadow mask.

The ionized gas can remove the material deposited on the shadow mask by sputtering.

In step (c), the pressure of the reactive gas in the deposition vacuum vessel can be between 1 millitorr and 500 millitorr.

### BRIEF DESCRIPTION OF THE DRAWINGS

FIG. 1 is a diagrammatic side view of an exemplary in-line production system for the manufacture of electronic elements and controlled elements on a substrate in accordance with the present invention;

FIG. 2 is a view of an isolated portion of a shadow mask utilized in the production system shown in FIG. 1;

FIG. 3 is a cross-sectional view of a portion of the substrate shown in FIG. 1 having an electronic element and a controlled element deposited thereon via the production system shown in FIG. 1;

FIGS. 4-9 are views of a sequential deposition of materials on a portion of substrate in FIG. 1 to form electronic elements thereon via the production system shown in FIG. 1; and

FIG. 10 is a flow diagram of a method of using and cleaning one or more shadow masks of the production system shown in FIG. 1.

### DETAILED DESCRIPTION OF THE INVENTION

An electronic device includes one or more electronic elements deposited on a substrate for controlling one or more controlled elements that may be separate from or an integral part of the electronic device and a method of manufacture thereof. In the following description, the electronic device described is an active matrix backplane having an array of organic light emitting diodes (OLEDs) which are deposited on the active matrix backplane and which are selectively controlled thereby. However, this is not to be construed as limiting the invention since any type of electronic element, such as a thin film transistor, a diode, a capacitor or a memory element, can be formed on the substrate for controlling any type of controlled element that may, or may not, be formed on the substrate. The following description will now be made with reference to the accompanying figures where like reference numbers correspond to like elements.

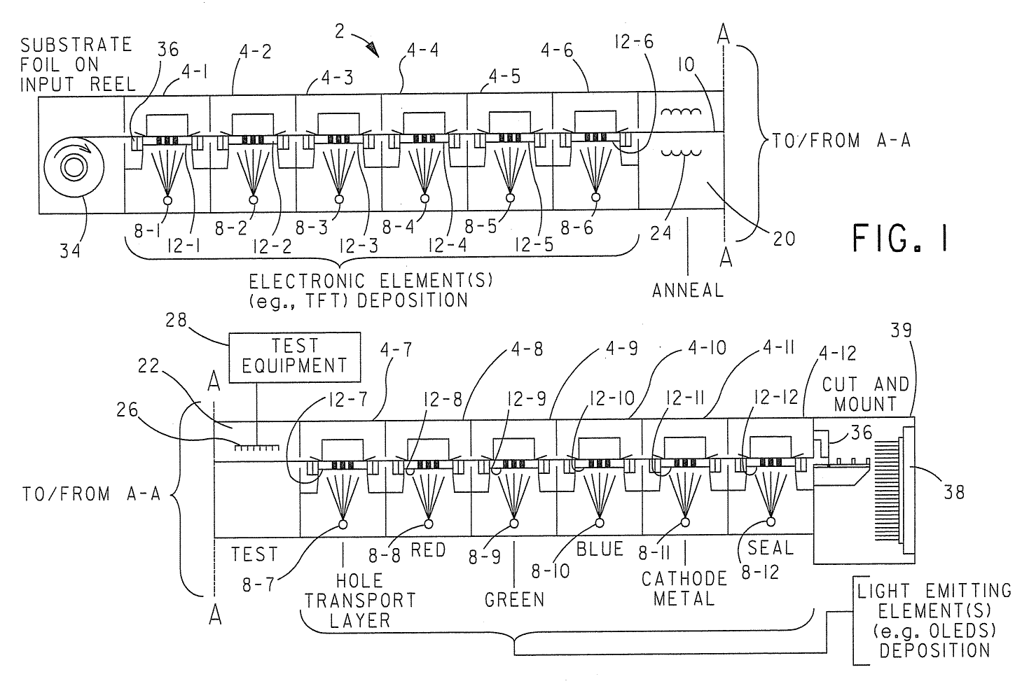

With reference to FIG. 1, an exemplary production system 2 for producing an electronic device, e.g., an active matrix backplane having OLEDs thereon, includes a plurality of vacuum vessels connected in series. The plurality of vacuum vessels includes a plurality of deposition vacuum vessels 4, an annealing vacuum vessel 20 and a test vacuum vessel 22. Each deposition vacuum vessel 4 includes a deposition source 8 that is charged with a desired material to be deposited onto a substrate 10 via a shadow mask 12 which is also positioned in the deposition vacuum vessel 4.

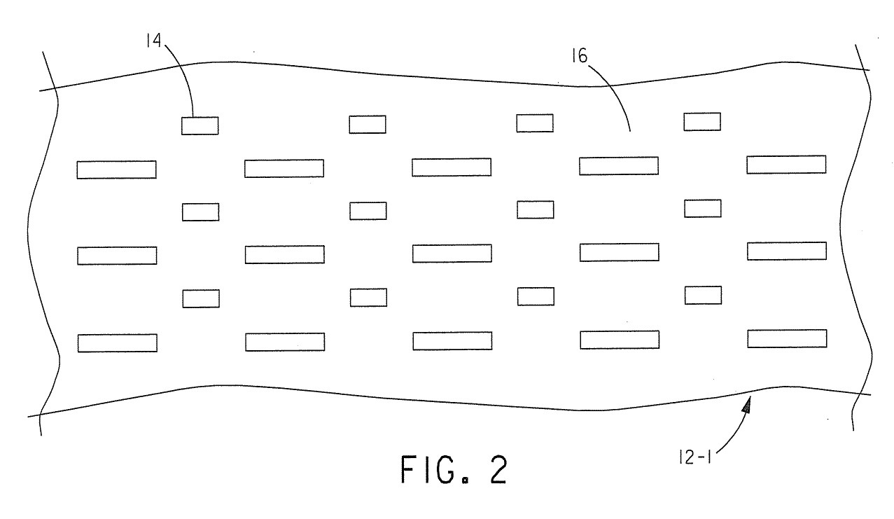

Each shadow mask 12-1-12-12 includes a pattern of apertures 14, e.g., slots, holes, etc., formed in a sheet 16. FIG. 2 shows a view of shadow mask 12-1 from the perspective of deposition source 8-1 of deposition vacuum vessel 4-1. The pattern of apertures 14 formed in sheet 16 of each shadow mask 12-1-12-12 corresponds to a desired pattern of material to be deposited on substrate 10 from deposition sources 8-1-8-12 in deposition vacuum vessel 4-1-4-12, respectively, as substrate 10 is advanced through each deposition vacuum vessel 4-1-4-12.

In the embodiment of production system 2 illustrated in FIG. 1, vacuum vessels 4-1-4-6 are utilized for depositing materials on substrate 10 to form one or more electronic elements on substrate 10. Each electronic element can be a thin film transistor (TFT), a diode, a memory element or a capacitor. For purpose of the following description, the one or more electronic elements will be described as a matrix of TFTs. However, this is not to be construed as limiting the invention. Vacuum vessels 4-7-4-11 are utilized for depositing materials on substrate 10 that form one or more controlled elements, e.g., OLEDs, that can be controlled by the TFT matrix deposited in deposition vacuum vessels 4-1-4-6. Deposition vacuum vessel 4-12 is utilized for depositing a protective seal over substrate 10 to protect the TFT matrix and the controlled elements deposited thereon from moisture and undesirable foreign particles, such as dust, dirt, and the like. If the one or more electronic elements deposited in deposition vacuum vessels 4-1-4-6 are to be utilized to control controlled elements not deposited on substrate 10 in vacuum vessels 4-7-4-11, these vacuum vessels 4-7-4-11 can be omitted and deposition vacuum vessel 4-12 can be positioned to receive substrate 10 when it is advanced from test vacuum vessel 22. Alternatively, vacuum vessels 22 and 4-7-4-12 can be omitted and a storage vessel 39 can be positioned to receive substrate 10 when it is advanced from anneal vacuum vessel 20. For purpose of illustration, deposition vacuum vessels 4-7-4-11 will be described as depositing the materials necessary to form OLEDs on substrate 10. However, this is not to be construed as limiting the invention. In addition, the number, purpose and arrangement of vacuum vessels 4, 20 and 22 is not to be construed as limiting the invention since such number, purpose and arrangement of vacuum vessels 4, 20 and 22 can be modified as needed by one of ordinary skill in the art for depositing one or more materials required for a particular application.

Anneal vacuum vessel 20 is positioned to receive substrate 10 when it is advanced from deposition vacuum vessel 4-6. Anneal vacuum vessel 20 includes heating elements 24 which are utilized to heat the materials deposited on substrate 10 in deposition vacuum vessels 4-1-4-6 to a suitable annealing temperature. After annealing, substrate 10 is advanced into test vacuum vessel 22 which includes a probe assembly 26 having probes (not shown) which can be moved into contacting or non-contacting relation, as required, with the TFT matrix deposited on substrate 10 for testing by test equipment 28.

When testing of the TFT matrix on substrate 10 in test vacuum vessel 22 is complete, substrate 10 is advanced through deposition vacuum vessels 4-7-4-12 where the materials forming the OLEDs are deposited on the TFT matrix and the seal coat is deposited over the TFT matrix and OLEDs.

Each vacuum vessel 4, 20 and 22 is connected to a source of vacuum (not shown) for establishing a suitable vacuum therein. More specifically, the source of vacuum establishes a suitable vacuum in deposition vacuum vessels 4-1-4-12 to enable a charge of desired material positioned in deposition sources 8-1-8-12 to be deposited on substrate 10 in a manner known in the art, e.g., sputtering, vapor phase deposition, etc., through the apertures 14 of the sheets 16 of shadow masks 12-1-12-12.

In the following description of exemplary production system 2, substrate 10 will be described as being a continuous flexible sheet which is initially disposed on a dispensing reel 34 that dispenses substrate 10 into deposition vacuum vessel 4-1. Dispensing reel 34 is positioned in a preload vacuum vessel 35 which is connected to a source of vacuum (not shown) for establishing a suitable vacuum therein. However, production system 2 can be configured to continuously process a plurality of individual substrates 10. Each deposition vacuum vessel 4 includes supports or guides 36 that avoid sagging of substrate 10 as it is advanced through deposition vacuum vessels 4-1-4-12.

In operation of production system 2, the material positioned in each deposition source 8-1-8-12 is deposited on substrate 10 in the presence of a suitable vacuum as substrate 10 is advanced through deposition vacuum vessel 4-1-4-12 whereupon plural progressive patterns are formed on substrate 10. More specifically, substrate 10 has plural portions that are positioned for a predetermined interval in each vacuum vessel 4, 20 and 22. During this predetermined interval, material is deposited from one or more of the deposition sources 8 onto the portion of substrate 10 positioned in the corresponding deposition vacuum vessel 4, the materials deposited on the portion of substrate 10 positioned in anneal vacuum vessel 20 are annealed and the TFT matrix deposited on the portion of the substrate 10 positioned in test vacuum vessel 22 is tested. After this predetermined interval, substrate 10 is step advanced whereupon the plural portions of substrate 10 are advanced to the next vacuum vessel 4, 20 or 22 in series for additional processing, as applicable. This step advancement continues until each portion of substrate 10 has passed through all of vacuum vessels 4, 20 and 22. Thereafter, each portion of substrate 10 exiting deposition vacuum vessel 4-12 is separated from the remainder of substrate 10 by cutter 36 whereafter this cut portion of substrate 10 is stored flat on a suitable storage means 38 positioned in a storage vacuum vessel 39. Alternatively, each portion of substrate 10 exiting deposition vacuum vessel 4-12 is received on a take-up reel (not shown) positioned in a storage vacuum vessel 39. Storage vacuum vessel 39 is connected to a source of vacuum (not shown) for establishing a suitable vacuum therein.

The description of substrate 10 as being a continuous flexible sheet is not to be construed as limiting the invention since substrate 10 can also be rigid and/or of any desired size or shape, e.g., one or more individual sheets, that can be positioned concurrently in one or more vacuum vessels 4, 20 and 22. For example, substrate 10 can be rigid and in the form of an elongated rectangle that can be positioned in one or more vacuum vessels 4, 20 and 22.

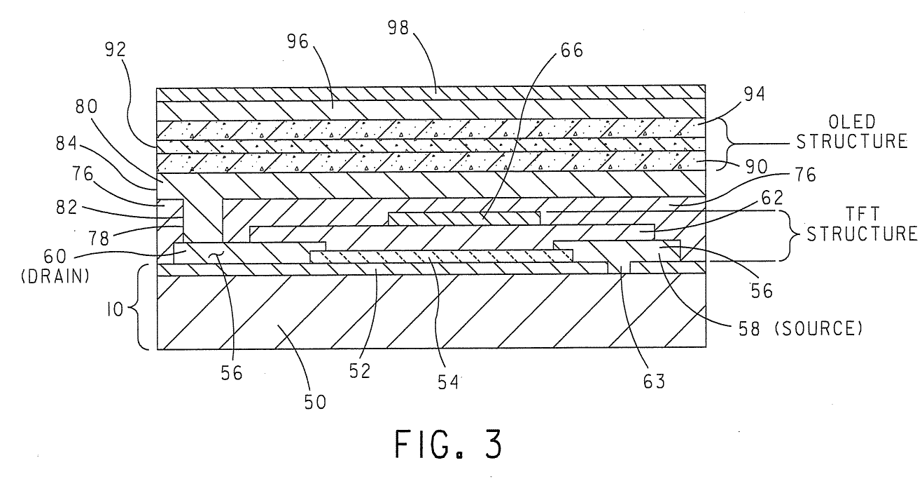

Next, a sequence of steps utilized to form an active matrix OLED display will be described with reference to FIGS. 3-9 and with continuing reference to FIG. 1.

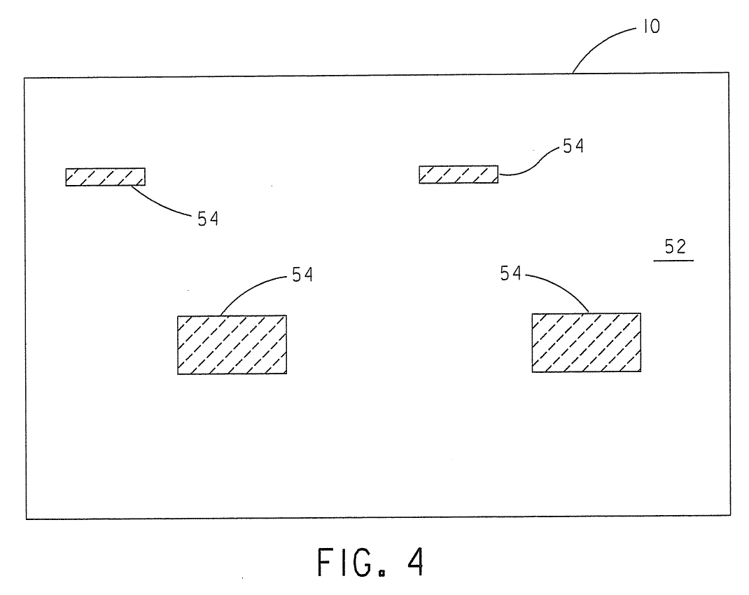

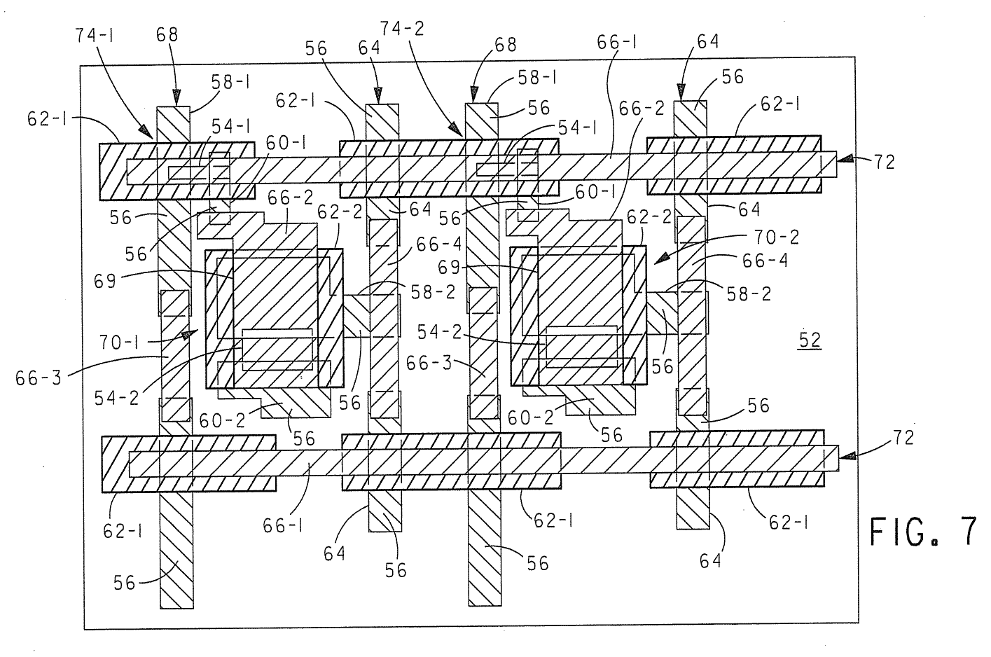

As shown in FIG. 3, substrate 10 includes an electrically conductive layer 50 having an insulator 52 on one surface thereof. A portion of substrate 10 is fed into deposition vacuum vessel 4-1 with electrical insulator layer 52 facing deposition source 8-1. In this exemplary deposition sequence, deposition 8-1 source is charged with a semiconductor material 54. This semiconductor material 54 is deposited by deposition source 8-1 on the surface of electrical insulator layer 52 opposite electrically conductive layer 50 through shadow mask 12-1. FIG. 4 shows an isolated view of the portion of substrate 10 that received the deposit of semiconductor material 54 on the surface of electrical insulator 52 to form pairs of transistors 70 and 74, shown best in FIG. 7.

The alignment of each shadow mask 12 to the portion of substrate 10 positioned in the corresponding deposition vacuum vessel 4 is critical. To this end, the portion of substrate 10 positioned in each deposition vacuum vessel 4 can include one or more fiducial marks or points (not shown) that an aligning means (not shown) positioned in each deposition vacuum vessel 4 can utilize for positioning the corresponding shadow mask 12 relative to the portion of substrate 10 received in the deposition vacuum vessel 4. Each aligning means can include optical or mechanical means for determining a position of the corresponding shadow mask to the fiducial marks on the portion of substrate 10 received in the corresponding deposition vacuum vessel 4. Each aligning means can also include drive means coupled to the corresponding shadow mask to perform x and y positioning of the shadow mask 12 relative to the one or more fiducial marks on the portion of substrate 10. This drive means can also include means for moving the shadow mask 12 into contact with the portion of substrate 10 for deposition of material thereon. Once the deposition of material onto substrate 10 in each deposition vacuum vessel 4 is complete, the drive means can separate the corresponding shadow mask 12 from the portion of substrate 10 received therein. This separation avoids shadow mask 12 from contacting the materials deposited on substrate 10 as substrate 10 is advanced into the next vacuum vessel 4, 20 or 22.

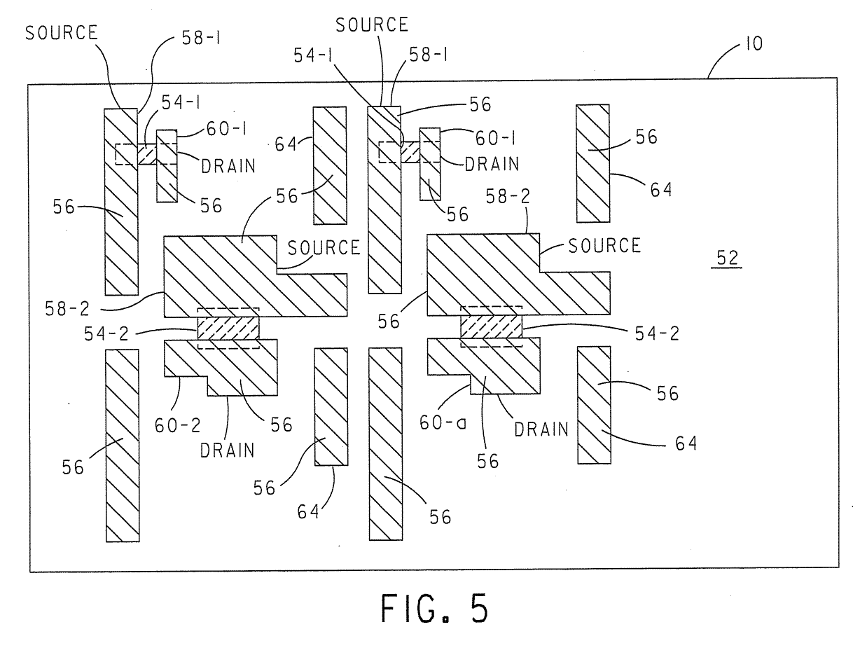

After deposition of semiconductor material 54 on electrical insulator layer 52 in deposition vacuum vessel 4-1, the portion of substrate 10 in deposition vacuum vessel 4-1 is advanced into deposition vacuum vessel 4-2. Deposition source 8-2 in deposition vacuum vessel 4-2 is charged with a semiconductor compatible conductive material 56 which is deposited on the portion of substrate 10 in deposition vacuum vessel 4-2 via shadow mask 12-2 to form the pattern of conducting material 56 shown in FIG. 5.

If substrate 10 has an elongated form, whereupon portions of substrate 10 can be positioned in two or more deposition vacuum vessels 4, 20 or 22, advancing the portion of substrate 10 from deposition vacuum vessel 4-1 into deposition vacuum vessel 4-2 advances another portion of substrate 10 into deposition vacuum vessel 4-1. In this manner, materials in different deposition vacuum vessels 4 can be deposited on different portions of substrate 10 at or about the same time. Similarly, annealing and testing of electronic elements deposited on various portions of substrate 10 can occur at or about the same time as one or more materials are being deposited on other portions of substrate 10. Thus, the exemplary production system 2 shown in FIG. 1 has the advantage of being able to simultaneously process plural portions of substrate 10 thereby maximizing the rate each portion of substrate 10 is processed to produce a completed electronic device.

As shown in FIGS. 3 and 5, a portion of conducting material 56 is deposited overlapping opposite sides or opposite ends of semiconductor material portions 54-1-54-2 to define source structures 58-1 and 58-2 and drain structures 60-1-60-2 for transistors 74 and 70, respectively.

Electrically conductive layer 50 of substrate 10 can be utilized as a power or ground bus depending on the application. To this end, as shown in FIG. 3, conducting material 56 forming each source 58 can be in electrical communication with electrically conductive layer 50 of substrate 10 by way of a through-hole or via 63 in electrical insulator layer 52. The via 63 utilized to connect each source 58 to electrically conductive layer 50 can be formed in electrical insulator layer 52 prior to introducing substrate 10 into any vacuum vessels 4, 20 or 22.

In the foregoing description, each source 58 is described as being connected to electrically conductive layer 50 by way of via 63 in electrical insulator layer 52. However, each source 58 can be connected to electrically conductive layer 50 by way of two or more vias 63. Alternatively, depending on the application, each drain 60 can be connected to electrically conductive layer 50 by way of two or more vias 63 in electrical insulator layer 52 while each source 58 remains electrically isolated from electrically conductive layer 50 by electrical insulator layer 52. The decision to connect each source 58 or each drain 60 to electrically conductive layer 50 by way of one or more vias 63 in electrical insulator layer 52 is a decision that can be readily made by one of ordinary skill in the art depending upon, among other things, the intended use of the electronic elements formed on substrate 10 and/or the intended use of electrically conductive layer 50 as a power bus or a ground bus.

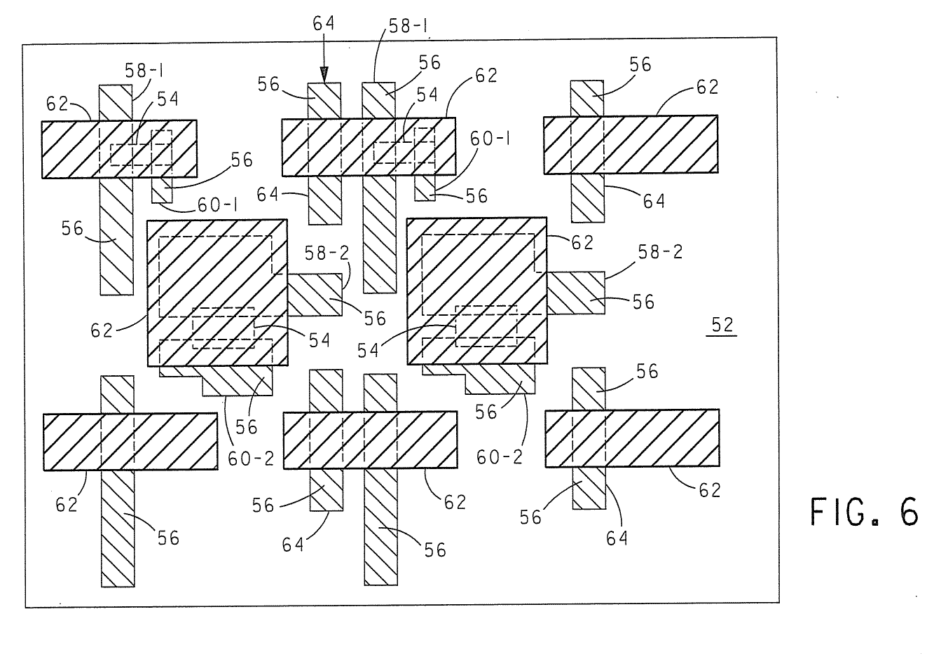

When the deposition of conducting material 56 is complete, the portion of substrate 10 in deposition vacuum vessel 4-2 is advanced to deposition vacuum vessel 4-3. Deposition source 8-3 is charged with an insulating material 62 which is deposited on the portion of substrate 10 positioned in deposition vacuum vessel 4-3 through shadow mask 12-3 in the pattern shown in FIG. 6.

As shown in FIGS. 3 and 6, insulating material 62 can cover all or part of each source 58 and each drain 60 formed by the deposition of conducting material 56 over semiconductor material 54. In addition, insulating material 62 can also cover portions of conducting material 56 that are to comprise a power bus 64 for each source 58-2.

Next, the portion of substrate 10 positioned in deposition vacuum vessel 4-3 is advanced to deposition vacuum vessel 4-4. Deposition source 8-4 is charged with a conducting material 66 which is deposited on the portion of substrate 10 positioned in deposition vacuum vessel 4-4 through shadow mask 12-4 in the pattern shown in FIG. 7. The conducting material portion 66-4 overlapping the rightward extension of each source 58-2 and the conducting material 56 in alignment with the portion of conducting material 66-4 completes the power bus 64 for the source 58-2 and for any like sources (not shown) in the same column as source 58-2. The conducting material portion 66-3 to the left of each source 58-2 forms a column bus 68 for source 58-1 and for any like sources (not shown) in the same column as source 58-2. The conducting material portion 66-2 is connected to drain 60-1 and covers a portion of the insulating material 62 that partially covers source 58-2 and drain 60-2 and is in spaced parallel relation with semiconducting material 54-2. Conducting material portion 66-2 defines a gate structure 69 that together with source 58-2, drain 60-2, insulating material portion 62-2 and semiconductor material 54-2 forms transistor 70.

A conducting material portion 66-1 deposited above each transistor 70 overlapping the horizontally oriented insulating material portion 62-1 forms a row select bus 72. More specifically, conducting material portion 66-1 above each transistor 70 forms with source 58-1, drain 60-1, semiconductor material 54-1 and the insulating material 62-1 therebetween a transistor 74 that controls the conductive state of transistor 70 having its gate structure 69 coupled to drain 60-1 of transistor 74. For example, transistor 74-1 controls the conduction state of transistor 70-1, and transistor 74-2 controls the conduction state of transistor 70-2.

In FIG. 7, row select bus 72 below each illustrated transistor 70 is utilized to select the row of transistors 74 below those shown in FIG. 7. To this end, it is to be appreciated that FIG. 7 only shows an isolated portion of substrate 10 having only portions of the materials utilized to form two pairs of transistors 74 and 70. The materials utilized to form other pairs of transistors 74 and 70 of the active matrix have been omitted from FIGS. 4-9 for simplicity of illustration.

With continuing reference to FIG. 7, when row select bus 72 above transistors 70-1 and 70-2 is selected, transistor 70-1 and 70-2 are responsive to the voltages applied to the column buses 68 associated with each transistor 74-1 and 74-2, respectively. Thus, when an appropriate voltage is applied to row select bus 72 above the illustrated transistors 70, the voltage applied to sources 58-1 of transistor 74-1 and 74-2 via their corresponding column buses 68 control the amount of current flowing in transistor 70-1 and 70-2, respectively. Thus, by simply controlling the voltage applied to each column bus 68 when an appropriate voltage is applied to the corresponding row bus, the amount of current flowing in each transistor 70 can be selectively controlled.

It is to be appreciated that each instance of conducting material portion 66, source 58, drain 60 and insulating material portion 62 defines a capacitor. More specifically, conducting material portion 66 defines a first plate of a capacitor which insulating material portion 62 holds in spaced relation to source 58 and drain 60 which, individually or collectively, define a second plate of the capacitor. If the leakage current thereof is sufficiently low, each capacitor can be utilized as a binary memory element.

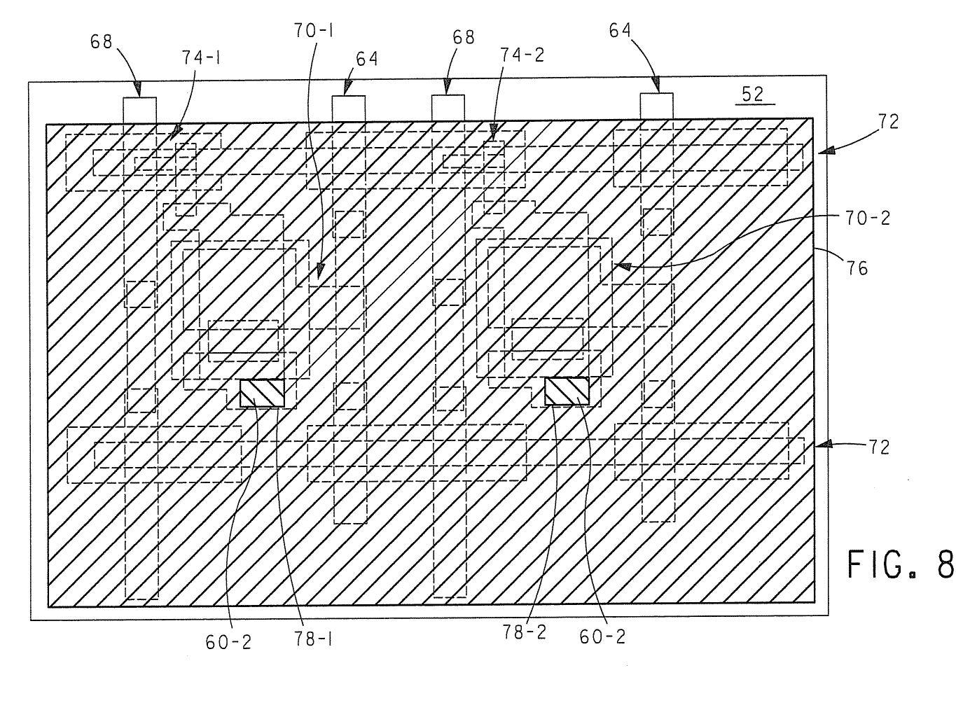

With reference to FIG. 8, and with ongoing reference to FIGS. 1 and 3-7, after the deposition of conducting material 66 is complete, the portion of substrate 10 in deposition vacuum vessel 4-4 is advanced into deposition vacuum vessel 4-5. Deposition source 8-5 is charged with an insulating material 76 which is deposited over substantially all of the material previously deposited on substrate 10 in the pattern shown in FIG. 8. In this pattern, however, portions 78-1 and 78-2 of drains 60-2 of transistor 70-1 and 70-2, respectively, are not covered by insulating material 76. In addition, the input ends of each power bus 64 and the input end of each column bus 68 are not covered by insulating material 76. Still further, the input end (not shown) of each row bus 72 is also not covered by insulating material 76. In the embodiment shown in FIGS. 4-9, the input end of each power bus 64 and the input end of each column bus 68 are at the top of the figure and the input end (not shown) of each row select bus 72 is to the right of the figure.

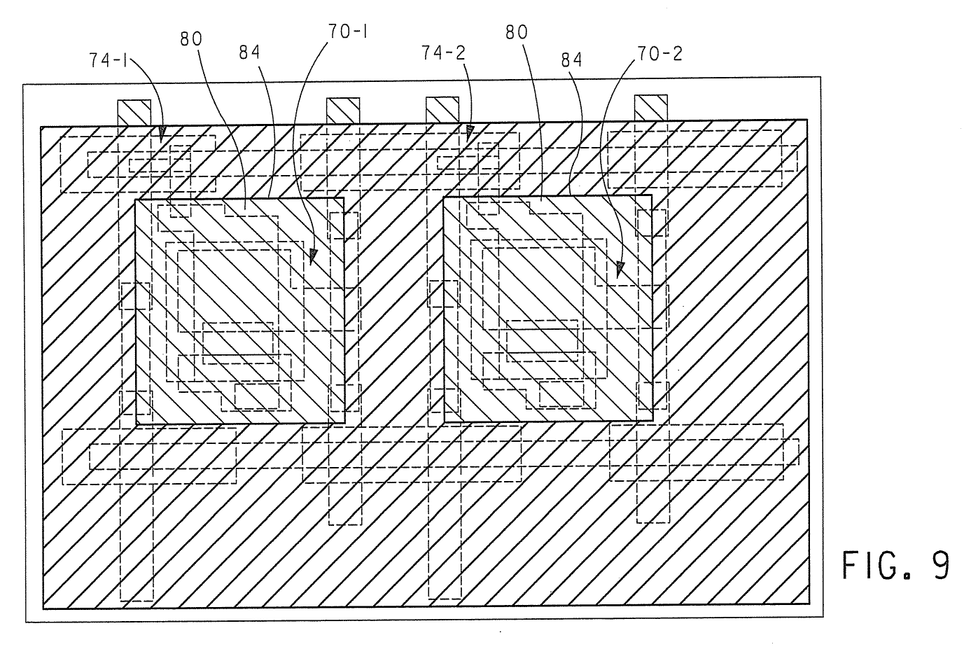

When the deposition of insulating material 76 is completed, the portion of substrate 10 in deposition vacuum vessel 4-5 is advanced into deposition vacuum vessel 4-6. Deposition source 8-6 is charged with a conducting material 80 that is deposited on substrate 10 through shadow mask 12-6 in the pattern shown in FIG. 9. As shown in FIG. 3, each portion 78 where insulating material 76 is not deposited in deposition vacuum vessel 4-5 defines a via through which conducting material 80 makes contact with drain 60-2 of the corresponding transistor 70. Conducting material 80 deposited above each transistor 70 defines an output pad 84, the voltage of which can be controlled by the associated pairs of transistors 70 and 74, e.g., transistors 70-1 and 74-1.

After conducting material 80 has been deposited, the portion of substrate 10 is advanced from deposition vacuum vessels 4-6 into anneal vacuum vessel 20 where one or more heating elements 24 are controlled to provide an appropriate annealing heat to the materials deposited on the portion of substrate 10 in deposition vacuum vessel 4-1-4-6.

The above described deposition steps and materials and the circuit produced thereby are for the purpose of illustration and are not to be construed as limiting the present invention since the deposition sequence, the deposition materials and/or the circuit produced thereby are matters of design choice that can be made by one of ordinary skill in the art. For example, the source and drain structures of each transistor can be reversed, the configuration and interconnections of the TFTs forming the circuit can be modified to suit a particular application, each TFT can be addressed individually or groups of TFT's can be addressed in any desired pattern, and so forth.

Each column bus 68 and row select bus 52 can be coupled to suitable row and column control logic (not shown) which can be formed on substrate 10 at the same time each transistor 70 and each transistor 74 is formed thereon. Specifically, each shadow mask 12 can include an appropriate pattern of apertures 14 in sheet 16 thereof which enable the formation on substrate 10 of appropriate row and column control logic at the same time each transistor 70 and each transistor 74 are formed thereon.

Depending upon the intended use of substrate 10 having plural thin film transistors 70 and 74 formed thereon, the annealing process may be the last step that the portion of substrate 10 receives. If so, the output of anneal vacuum vessel 20 is coupled to storage means 38 which stores the portion of substrate 10 for subsequent processing or use. However, if the portion of substrate 10 is to be exposed to additional processing steps, e.g., to form OLEDs on output pads 84, the portion of substrate 10 can be advanced into test vacuum vessel 22 for testing thereof.

In test vacuum vessel 22, the probes of probe assembly 26 are moved into contacting or non-contacting relation, as required, with the various buses 64, 68 and 72 and output pads 84. Thereafter, under the control of test equipment 28 via probe assembly 26, the transistor pair 70 and 74 associated with each output pad 84 can be tested.

If such test fails, the portion of substrate 10 failing the test is identified or designated accordingly, and, preferably, receives no further processing. However, if such test passes, the portion of substrate 10 can be subjected to further processing as shown in FIG. 1.

In the case where each output pad receives depositions to form an OLED, the portion of substrate 10 is advanced from test vacuum vessel 22 into deposition vacuum vessel 4-7. Deposition source 8-7 is charged with a hole transport material such as NPB (C₄₄H₃₂N₂) which is deposited through shadow mask 12-7 to form a hole transport layer 90 on each output pad 84 as shown in FIG. 3.

After deposition of hole transport layer 90, the portion of substrate 10 is advanced into deposition vacuum vessel 4-8. Deposition source 8-8 comprises two separately controllable deposition sources for depositing an emitter layer 92 comprised of an emitter material deposited by one deposition source and a dopant deposited by the other deposition source. In the case where deposition source 8-8 is utilized to form a red light emitting diode, the emitter material can be 98%-99.5% by weight of DCM (C₂₃H₂₁N₃O) and 2%-0.5% by weight of DMQA (C₂₂H₁₆N₂O₃). During deposition, deposition source 8-8 is controlled to deposit the emitter material and the dopant in the foregoing percentages to form emitter layer 92 on the hole transport layer 90 of every third output pad 84.

After emitter layer 92 is deposited to a sufficient extent, deposition source 8-8 is controlled to terminate the deposition of dopant material while continuing the deposition of emitter material. This continued deposition of emitter material absent dopant forms an electron transport layer 94 on the just deposited emitter layer 92 as shown in FIG. 3.

When the deposition of materials in deposition vacuum vessel 4-8 is complete, the portion of the substrate is sequentially stepped through deposition vacuum vessels 4-9 and 4-10 where deposition sources 8-9 and 8-10, respectively, deposit green and blue emitter layers 92 and electron transport layers 94 in the manner discussed above to form a plurality of a color triads on the portion of substrate 10. Each color triad includes separately controllable red, green and blue OLEDs.

To form green OLEDs, deposition source 8-9 co-deposits emitter material, such as Alq₃ (C₂₇H₁₈AlN₃O₃), and dopant, such as Coumarin 153 (C₁₆H₁₄F₃O₂), to form the emitter layers 92 of the green light emitting diodes and deposits only the emitter material to form the electron transport layer 94 of the green light emitting diodes. To form the blue OLEDs, deposition source 8-10 co-deposits an emitter material, such as PPD (C₅₂H₃₆N₂), and dopant, such as perylene (C₂₀H₁₂), to form the emitter layer 92 of the blue light emitting diodes and deposits only the emitter material to form the electron transport layer 94 of the blue light emitting diodes.

After each layer 90, 92 and 94 has been deposited on the output pads 84 to form the color triads discussed above, the portion of substrate 10 is advanced into deposition vacuum vessel 4-11. Deposition source 8-11 is charged with a conductive material 96 which is deposited through shadow mask 12-11 onto the layer of electron transport material 94 of each OLED. More preferably, providing conductive material 96 does not contact any of the conducting material 80 forming each output pad 84, conducting material 96 is deposited as a contiguous layer over all of the OLEDs formed on the portion of substrate 10. In this manner, it is only necessary to contact this contiguous layer of conducting material at a few points in order to form a cathode 98 for all of the OLEDs formed on the portion of substrate 10. In this configuration, the layer of conductive material 96 acts as a common cathode structure for all of the OLEDs formed on the portion of substrate 10 while the output pad 84 associated with each OLED operates as an anode structure for the OLED structure associated therewith. If conductive material 96 is only deposited over the OLED structure associated with each output pad 84, it will be necessary to connect each deposit of conducting material 96 to an appropriate cathode bias source.

After conducting material 96 has been deposited, the portion of substrate 10 is advanced from deposition vacuum vessel 4-11 to deposition vacuum vessel 4-12. Deposition source 8-12 is charged with a sealing material 98 which is deposited through a shadow mask 12-12 onto substantially all of the exposed surface of the materials deposited on the portion of substrate 10. To enable electrical contact to be made with buses 64, 68, 72 and the one or more deposits of conducting material 96, sealing material 98 is not deposited on the input ends of buses 64, 68, 72 nor is sealing material 98 deposited on all or part of the one or more deposits of conducting material 96 Sealing material 98 is configured to avoid moisture and particulate matter from contacting any of the deposited materials other than those portions of the deposited materials that have been intentionally left exposed.

Alternatively, deposition vacuum vessel 4-12 can be considered to be representative of a plurality of series connected deposition vacuum vessels disposed between deposition vacuum vessel 4-11 and storage vacuum vessel 39. Each of these series connected deposition vacuum vessels can include a deposition source 8 charged with a suitable material which is deposited through a shadow mask 12 on one or more portions of substrate 10 as it is advanced therethrough to form a protective seal thereover. A system which can be adapted for use in the embodiment of production system 2 shown in FIG. 1 is the Guardian™ tool, designed by Vitec Systems, Inc. of San Jose, Calif. This system includes series connected deposition vacuum vessels for depositing a liquid monomer on substantially all of the exposed surfaces of materials deposited on the portion of substrate 10 to create a microscopically flat surface. The liquid monomer is then hardened (polymerized) into a solid polymer film. A first layer of transparent ceramic is then deposited to create a first barrier, and a second polymer layer is applied to protect the barrier and create a second flat surface. This barrier/polymer combination is repeated as necessary until a desired level of impermeability is achieved.

In the foregoing description, it has been assumed that substrate 10 is a continuous sheet. After sealing material 98 is deposited, the portion of substrate 10 in deposition vacuum vessel 4-12 is advanced therefrom whereupon cutter 36 cuts the portion of substrate 10 from the remainder of substrate 10. Thereafter, the cut portion of substrate 10 is stored in storage means 38 of storage vacuum vessel 39 for subsequent processing or use. Alternatively, cutter 36 can be replaced with a take-up reel (not shown) which receives substrate 10 as it is advanced from deposition vacuum vessel 4-12.

The deposition of materials through shadow masks 12 described above is for the purpose of illustrating the invention and is in no way to be construed as limiting the invention. As would be apparent to one of ordinary skill in the art, more than one shadow mask 12 may be required in a single deposition vacuum vessel 4 in order to form the pattern described. For example, in order to deposit insulating material 76 in the manner shown in FIG. 8, two or more shadow masks 12 may be employed, either simultaneously or one at a time, to deposit the pattern of insulating material 76 shown. To this end, deposition vacuum vessel 4-5 may include means (not shown) for exchanging the various shadow masks needed to deposit the pattern of insulating material 76 shown. Alternatively, deposition vacuum vessel 4-5 can be considered to be representative of a plurality of series connected deposition vacuum vessels disposed between deposition vacuum vessels 4-4 and 4-6. Each of these series connected deposition vacuum vessels can include a deposition source 8 charged with insulating material 76 which is deposited through a shadow mask 12 on a select portion of substrate 10 as it is advanced therethrough. Collectively, the deposition of insulating material 76 by these series connected deposition vacuum vessels would produce the pattern of insulating material 76 shown in FIG. 8. Similarly, the deposition of conducting material 66 to form conducting material portions 66-1-66-4 may require a plurality of shadow masks 12, each having a different pattern of apertures 14 therein, interchangeably positionable in deposition vacuum vessel 4-4. Alternatively, deposition vacuum vessel 4-4 can be considered to be representative of a plurality of series connected deposition vacuum vessels disposed between deposition vacuum vessels 4-3 and 4-5. Each of these series connected deposition vacuum vessels can include a deposition source 8 charged with conducting material 66 which is deposited through one of the shadow masks on a select portion of substrate 10 as it is advanced therethrough. Collectively, the deposition of conducting material 66 by these series connected deposition vacuum vessels would produce the pattern of conducting material 66 shown in FIG. 7. Similar comments apply in respect of any other shadow mask 12 where the volume of apertures 14 therein adversely affects the structural rigidity of the sheet 16 forming the shadow mask 12.

In order to reduce or avoid or eliminate the build-up of material from each deposition source 8 on each shadow mask 12 of system 2 during use thereof, a suitable pressure of reactive gas can be introduced into the deposition vacuum vessel 4 housing the shadow mask 12 at one or more suitable times when said deposition vacuum vessel 4 is not being used for depositing material. The suitable pressure of reactive gas in each deposition vacuum chamber 4 is desirable between 1 millitorr and 500 millitorr. However, this is not to be construed as limiting the invention since it is envisioned that the pressure of the reactive gas in the deposition vacuum vessel can be selected by one of ordinary skill in the art to accomplish the cleaning of the shadow mask in a manner described next.

The reactive gas in the deposition vacuum vessel 4 can be stimulated (ignited) in a manner known in the art, i.e., by application of a suitable RF electric field to the reactive gas, such that the stimulated reactive gas selectively etches material(s) deposited on the shadow mask 12 in a process know as reactive ion etching (RIE). Desirably, the reactive gas introduced into each deposition vacuum vessel 4 is selected based on its ability for RIE the material(s) deposited on the corresponding shadow mask 12 while avoiding or minimizing the etching of the material forming the shadow mask 12 itself (which may be made from, e.g., without limitation, Invar® or Kovar®). For example, without limitation, CF₄ or SF₆ can be used for RIE an insulator, such as, without limitation, SiO₂, that may deposited or which may form on substrate 10 or material(s) deposited on substrate 10. Chlorine type gases, such as a combination of Cl₂ and BCl₃, can be used for RIE electrically conductive material(s), such as, without limitation, Cu and Al, deposited on substrate 10. Lastly, trimethylamine, CH₄/H₂/Ar or H₂/Ar can be used for RIE semiconductor material(s), such as, without limitation, CdS, CdTe and CdSe, deposited on substrate 10.

RIE works as follows. Reactive gas in a deposition vacuum vessel 4 is exposed to a strong RF (radio frequency) electromagnetic field which converts the reactive gas into a plasma. A typical frequency of the RF electromagnetic field is 13.56 megahertz, applied at a few hundred watts. The oscillating electric field ionizes the reactive gas molecules by stripping them of electrons, creating a plasma. In each cycle of the electric field, the electrons are electrically accelerated up and down in the deposition vacuum vessel 4, sometimes striking both interior surfaces of the vacuum deposition vessel 4 and the shadow mask 12 (or the material deposited on the shadow mask) position therein. At the same time, the much more massive ions move relatively little in response to the RF electromagnetic field. When the electrons are absorbed into the interior surfaces of the deposition vacuum vessel 4, they are simply fed out to ground and do not alter the electronic state of the system. However, electrons absorbed into the shadow mask 12 (or the material deposited on the shadow mask) inside the deposition vacuum vessel 4 cause the shadow mask 12 to build up a negative charge which develops a large negative voltage, e.g., around a few hundred volts. The plasma itself develops a slightly positive charge due to the higher concentration of positive ions compared to free electrons.

Because of this large voltage difference, positive ions drift toward the shadow mask 12, where they collide with the material that has built up on the shadow mask 12 as a result of the deposit of material thereon during one or more deposition events. These ions react chemically with the material deposited on the surface of the shadow mask by the corresponding deposition source 8, but also knock off (sputter) some material by transferring some of their kinetic energy.

Desirably, the RIE ions travel in the direction substantially perpendicular to the surface of the shadow mask 12 that faces the deposition source 8, whereupon RIE produces substantially anisotropic etch profiles. However, this is not to be construed as limiting the invention.

An advantage of RIE material deposited on a shadow mask 12 of system 2 in-situ (i.e., within the vacuum vessel 4 housing the shadow mask 12) is that such cleaning of shadow mask 12 can occur without having to remove shadow mask 12 from its vacuum vessel 4, thereby maintaining alignment of shadow mask 12 within vacuum vessel 4 for the subsequent deposition of material on another substrate 10. Another advantage of in-situ RIE cleaning of shadow masks 12 is that the available production time of system 2 is increased versus removing shadow masks 12 from deposition vacuum vessels 4 of system 2 for cleaning, which removal requires at least temporary removal of at least one vacuum vessels 4 of system 2 from production use. Still another advantage is that RIE can be used often to maintain the shadow masks 12 clean, whereupon the patterns produced by said shadow masks 12 are more consistent and long RIE times can be avoided.

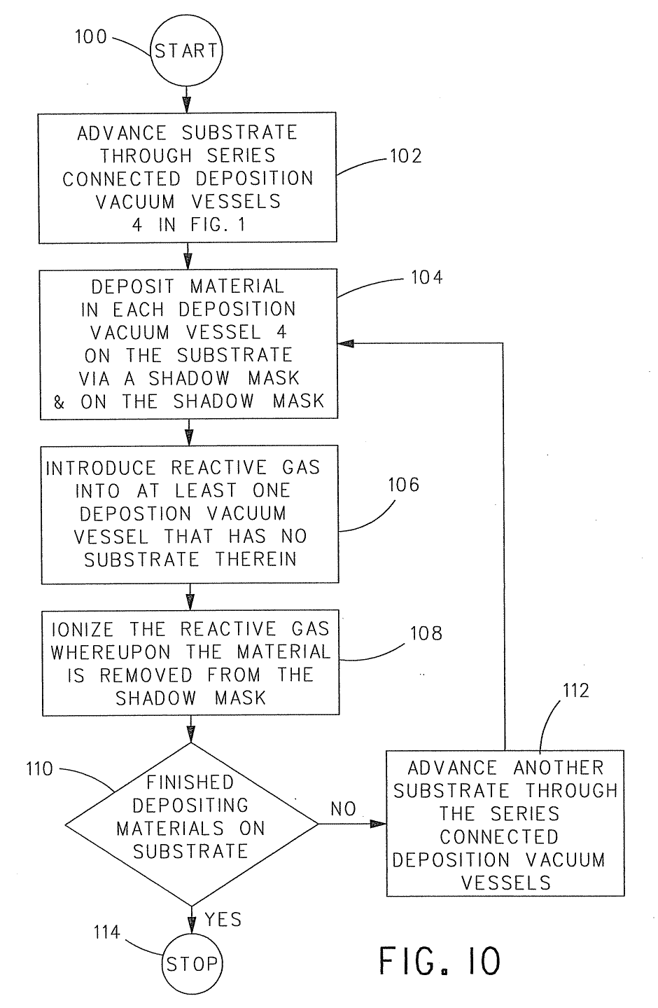

With reference to FIG. 10 and with reference back to FIG. 1, a method of using and cleaning one or more shadow masks of production system 2, e.g., shadow mask vapor deposition system, used to form an electronic device will now be described.

Initially, the method advances from start step 100 to step 102. In step 102, a substrate is advanced through a plurality of series connected deposition vacuum vessels 4. Each deposition vacuum vessel 4 has at least one material deposition source 8 and a shadow mask 12 positioned therein.

The method then advances a step 104, wherein the material from at least one material deposition source 8 positioned in each deposition vacuum vessel 4 is deposited on the substrate 10 in the presence of a vacuum in the deposition vacuum vessel 4 through the pattern of apertures 14 in the shadow mask 12 positioned therein. The material is also deposited on a surface of the shadow mask 12 facing the material deposition source 8.

The method then advances to step 106 wherein, after the substrate has been removed from the deposition vacuum vessel 4, a reactive gas is introduced into the deposition vacuum vessel 4.

The method then advances to step 108, wherein the reactive gas is ionized in the deposition vacuum vessel 4, whereupon the ionized gas removes the material deposited on the shadow mask 12.

Steps 104-108 can be repeated on an as-needed basis for each deposition vacuum vessel 4 of the series connected deposition vacuum vessels 4 shown in FIG. 1. Thus, for example, it may be desirable to clean each shadow mask 12 used for depositing one material, e.g., semiconductor material, more often than each shadow mask utilized to deposit another material, e.g., an insulator or a conductor. Also or alternatively, the time for cleaning each shadow mask may be based upon the amount of material being deposited thereon. Thus, a shadow mask used for depositing a greater volume of material therethrough may require RIE more often than a shadow mask that is utilized for depositing less material therethrough.

Desirably, when RIE of material on a shadow mask is underway, the substrate is not positioned in the deposition vacuum vessel to avoid inadvertent RIE of any material deposited thereon, especially through the apertures 14 of the shadow mask 12.

With reference back to the flow diagram of FIG. 10, upon completion of RIE of the material on the shadow mask in step 108, the method advances to step 110, where a decision is made whether the deposition vacuum vessels 4 will be utilized for depositing materials on another substrate 10 passing therethrough. If additional depositions of materials on another substrate 10 moving through deposition vacuum vessels 4 is to occur the method advances to step 112, wherein the other substrate is advanced through the series connected deposition vacuum vessels. Thereafter, steps 104-110, and step 112, are repeated as necessary for each additional substrate advanced through the series connected deposition vacuum vessels 4 in FIG. 1.

If upon any iteration of step 110 it is determined that no additional materials are to be deposited on other substrates advancing through the deposition vacuum vessels 4 in FIG. 1, the method advances to stop step 114.

While the flowchart of FIG. 10 is described in connection with the series connected vacuum deposition vacuum vessels 4 shown in FIG. 1, it is to be appreciated that the method is also applicable to a single deposition vacuum vessel 4.

The invention has been described with reference to the preferred embodiments. Obvious modifications and alterations will occur to others upon reading and understanding the foregoing detailed description. It is intended that the invention be construed as including all such modifications and alterations insofar as they come within the scope of the appended claims or the equivalents thereof.

The invention claimed is:

1. A method of using and cleaning one or more shadow masks of a shadow mask vapor deposition system used to form an electronic device, the method comprising:
(a) advancing a substrate through a plurality of series connected deposition vacuum vessels, with each deposition vacuum vessel having at least one material deposition source and a shadow mask positioned therein;
(b) depositing on the substrate in the presence of a vacuum in each deposition vacuum vessel the material from the at least one material deposition source positioned in the deposition vacuum vessel through the shadow mask positioned therein, wherein said material is also deposited on a surface of the shadow mask that faces the one material deposition source;
(c) following the deposit in step (b) of the material on the surface of the shadow mask in at least one deposition vacuum vessel of said plurality of series connected deposition vacuum vessels, introducing a reactive gas into the one deposition vacuum vessel when the one deposition vacuum vessel has no substrate therein; and
(d) ionizing the reactive gas in the one deposition vacuum vessel of said plurality of series connected deposition vacuum vessels whereupon the ionized gas removes the material deposited on the shadow mask.

2. The method of claim 1, further including:
(e) advancing another substrate through the plurality of series connected deposition vacuum vessels;
(f) depositing on the other substrate in the presence of a vacuum in each deposition vacuum vessel the material from the at least one material deposition source positioned in the deposition vacuum vessel through the shadow mask positioned therein, wherein said material is also deposited on a surface of the shadow mask that faces the one material deposition source;
(g) following the deposit in step (f) of the material on the surface of the shadow mask in at least one deposition vacuum vessel of said plurality of series connected deposition vacuum vessels, introducing a reactive gas into the one deposition vacuum vessel when the one deposition vacuum vessel has no substrate therein; and
(h) ionizing the reactive gas in the one deposition vacuum vessel of said plurality of series connected deposition vacuum vessels whereupon the ionized gas removes the material deposited on the shadow mask.

3. The method of claim 1, wherein, in step (d), the ionized gas removes the material deposited on the shadow mask by sputtering.

4. The method of claim 1, wherein, in step (c), the pressure of the reactive gas in the one deposition vacuum vessel is between 1 millitorr and 500 millitorr.

5. The method of claim 1, wherein the reactive gas is either CF₄ or SF₆ when the material deposited on the shadow mask is an insulator.

6. The method of claim 5, wherein the insulator is SiO₂.

7. The method of claim 1, wherein the reactive gas is a chlorine type gas when the material deposited on the shadow mask is electrically conductive.

8. The method of claim 7, wherein:
the chlorine type gas includes one or a combination of Cl₂ and BCl₃; and
the electrically conductive material is either Cu or Al.

9. The method of claim 1, wherein the reactive gas is either trimethylamine, the combination of CH₄/H₂/Ar or the combination of H₂/Ar when the material deposited on the shadow mask is a semiconductor.

10. The method of claim 9, wherein the semiconductor is either CdS, CdTe or CdSe.

11. A method of using and cleaning one or more shadow masks of a shadow mask vapor deposition system used to form an electronic device, the method comprising:
(a) introducing a substrate into a deposition vacuum vessel that includes a material deposition source and a shadow mask therein;
(b) depositing on the substrate in the presence of a vacuum in the deposition vacuum vessel the material from the material deposition source through the shadow mask, wherein said material is also deposited on a surface of the shadow mask that faces the material deposition source;
(c) following the deposit in step (b) of the material on the surface of the shadow mask in the deposition vacuum vessel, introducing a reactive gas into the deposition vacuum vessel in the absence of the substrate therein; and
(d) ionizing the reactive gas in the deposition vacuum vessel whereupon the ionized gas removes the material deposited on the shadow mask.

12. The method of claim 11, further including:
(e) introducing another substrate into the deposition vacuum vessel;
(f) depositing on the other substrate in the presence of a vacuum in the deposition vacuum vessel the material from the material deposition source through the shadow mask, wherein said material is also deposited on a surface of the shadow mask that faces the material deposition source;
(g) following the deposit in step (f) of the material on the surface of the shadow mask in the deposition vacuum vessel, introducing a reactive gas into the deposition vacuum vessel in the absence of the other substrate therein; and
(h) ionizing the reactive gas in the deposition vacuum vessel whereupon the ionized gas removes the material deposited on the shadow mask.

13. The method of claim 11, wherein, in step (d), the ionized gas removes the material deposited on the shadow mask by sputtering.

14. The method of claim 11, wherein, in step (c), the pressure of the reactive gas in the deposition vacuum vessel is between 1 millitorr and 500 millitorr.
